(19) United States
(12) Patent Application Publication
(10) Pub. No.: US 2025/0070718 A1
(43) Pub. Date: Feb. 27, 2025

(54) AMPLIFIER CIRCUIT AND AMPLIFYING METHOD

(71) Applicant: Murata Manufacturing Co., Ltd., Nagaokakyo-shi (JP)

(72) Inventors: John HOVERSTEN, Waltham, MA (US); David Perreault, Waltham, MA (US); Yevgeniy Tkachenko, Waltham, MA (US); Takeshi Kogure, Nagaokakyo-shi (JP); Yuuki Fukuda, Nagaokakyo-shi (JP); Toshiki Matsui, Nagaokakyo-shi (JP); Yuuma Noguchi, Nagaokakyo-shi (JP); Kiichiro Takenaka, Nagaokakyo-shi (JP)

(21) Appl. No.: 18/943,524

(22) Filed: Nov. 11, 2024

Related U.S. Application Data
(63) Continuation of application No. PCT/JP2023/015459, filed on Apr. 18, 2023.
(60) Provisional application No. 63/343,198, filed on May 18, 2022.

(51) Int. Cl. H03F 1/02; H03F 3/213

(52) U.S. Cl. CPC H03F 1/0205; H03F 3/213; H03F 2200/102; H03F 2200/451

(57) ABSTRACT

An amplifier circuit is provided for amplifying a radio frequency signal within one frame of a radio frequency signal by using multiple discrete voltages supplied from the tracker circuit. The amplifier circuit includes a power amplifier and an RC series circuit including a resistor and a capacitor that are connected in series between the ground and a voltage supply path between the tracker circuit and the power amplifier.

### CROSS REFERENCE TO RELATED APPLICATIONS

This application is a continuation of International Application No. PCT/JP2023/015459, filed Apr. 18, 2023, which claims priority to U.S. Provisional Patent Application No. 63/343, 198, filed May 18, 2022, the entire contents of each of which are hereby incorporated by reference in their entireties.

### TECHNICAL FIELD

The present disclosure relates to an amplifier circuit and an amplifying method.

### BACKGROUND

Recently, the envelope tracking (ET) mode has been applied to power amplifier circuits, achieving improvement of their power-added efficiency (PAE). U.S. Pat. No. 9,755, 672 (the “'672 Patent”) discloses a technique of supplying multiple discrete voltages to a power amplifier circuit in the ET mode.

However, supply of multiple discrete voltages to an amplifier circuit as described in the 672 Patent may degrade the amplification characteristics of the amplifier circuit.

### SUMMARY OF THE INVENTION

In view of the foregoing, the exemplary aspects of the present disclosure provide an amplifier circuit and an amplifying method that enable the radio-frequency signal amplification characteristics to be improved.

In an exemplary aspect, an amplifier circuit is provided that is configured to amplify a radio frequency signal by using a plurality of discrete voltages supplied from a tracker circuit within one frame of the radio frequency signal. The amplifier circuit includes a power amplifier, and an RC series circuit that includes a resistor and a first capacitor, which are connected in series between the ground and a voltage supply path between the tracker circuit and the power amplifier.

In another exemplary aspect, an amplifier circuit is provided that includes a power amplifier, an RC series circuit that includes a resistor and a first capacitor, which are connected in series between the ground and a voltage supply path for the power amplifier, and a first bypass capacitor circuit that includes a second capacitor connected between the ground and the voltage supply path.

In another exemplary aspect, an amplifying method is provided for amplifying a radio frequency signal. In this aspect, the method includes receiving supply of a plurality of discrete voltages within one frame of the radio frequency signal; attenuating ringing of the plurality of discrete voltages by using an RC series circuit; and amplifying the radio frequency signal by using the plurality of discrete voltages whose ringing has been attenuated.

The exemplary aspects of the present disclosure improve radio-frequency signal amplification characteristics.

### BRIEF DESCRIPTION OF DRAWINGS

FIG. 1A is a graph showing a transition example of power supply voltage in an average power tracking mode in an exemplary aspect.

FIG. 1B is a graph showing a transition example of power supply voltage in a digital envelope tracking mode in an exemplary aspect.

FIG. 1C is a graph showing a transition example of

power supply voltage in an analog envelope tracking mode in an exemplary aspect.

FIG. 2 is a diagram illustrating the circuit configuration of a communication device according to an exemplary embodiment.

FIG. 3 is a flowchart of an amplifying method according to an exemplary embodiment.

FIG. 4 is a plan view of a power amplifier module according to an exemplary embodiment.

FIG. 5 is a plan view of a power amplifier module according to an exemplary embodiment.

### DETAILED DESCRIPTION OF EMBODIMENTS

Exemplary embodiments of the present disclosure will be described below in detail by using the drawings. Each embodiment described below is a comprehensive or concrete example. The numeral values, the shapes, the materials, the components, the layout and the connection form of components, and the like described in the embodiments described below are exemplary, and are not intended to limit the present invention.

It is also noted that the figures are schematic views with appropriate emphasis, abbreviation, or adjustment of ratios for illustration of the present disclosure, and are not necessarily illustrated strictly. The shapes, the positional relationship, and the ratios may be different from the actual ones. In the figures, substantially the same configurations are designated with the same reference numerals. Repeated description may be skipped or simplified.

In the figures described below and for purposes of this disclosure, x axis and y axis are orthogonal to each other in a plane parallel to a principal surface of a module substrate. Specifically, when a module substrate is rectangular in a plan view, x axis is parallel to a first side of the module substrate; y axis is parallel to a second side orthogonal to the first side of the module substrate. In addition, z axis is perpendicular to the principal surface of the module substrate. The positive direction of z axis indicates the upward direction; its negative direction indicates the downward direction.

In a circuit configuration in the present disclosure, the term “to be connected” encompasses, not only the case of direct connection using a connection terminal and/or a wiring conductor, but also the case of electrical connection via other circuit devices. Moreover, “to be connected between A and B” generally refers to a connection, between A and B, to both A and B, and refers to a connection in series to a path between A to B. The phrase “a path between A and B” refers to a path formed by a conductor that electrically connects A to B.

In a component layout in the present disclosure, the phrase “to dispose a component on/in a substrate” encompasses placement of the component on a principal surface of the substrate and placement of the component in the substrate. Moreover, the phrase “to dispose a component on a principal surface of a substrate” encompasses, in addition to placement of the component that is in contact with the principal surface of the substrate, placement of the component above the principal surface without contact with the principal surface (for example, stacking the component on a different component which is disposed so as to be in contact with the principal surface). The phrase, “to dispose a component on a principal surface of a substrate” may encompass placement of the component in a recess formed on the principal surface in an exemplary aspect. The phrase “to dispose a component in a substrate” encompasses, in addition to the component encapsulated in the module substrate, the component, all of which is disposed between the principal surfaces of the substrate but a part of which is not covered by the substrate, and the component, only a part of which is disposed in the substrate.

In a component layout in the present disclosure, the phrase “plan view of a module substrate” refers to viewing an object or component subjected to orthogonal projection to the xy plane from the z-axis positive side. “In plan view, A overlaps B” means that at least part of the area of A subjected to orthogonal projection to the xy plane overlaps at least part of the area of B subjected to orthogonal projection to the xy plane. The phrase “a is disposed between B and C” means that at least one of line segments connecting any points in B to any points in C passes through A.

In the present disclosure, the term “terminal” refers to a point where a conductor in a component terminates. When the impedance of a path between components is sufficiently low, a terminal is interpreted, not only as a single point, but also as any point on the path between the components or as the entire path.

It is also noted that terms which indicate relationship between components, such as “parallel” and “perpendicular”, terms which indicate the shapes of components, such as “rectangular”, and numerical ranges do not represent only strict meaning, and mean substantially equivalent ranges, for example, having errors in the order of a few percent.

### EXEMPLARY EMBODIMENT

An exemplary embodiment will be described below by referring to the drawings.

### 1.1 Description of Tracking Mode

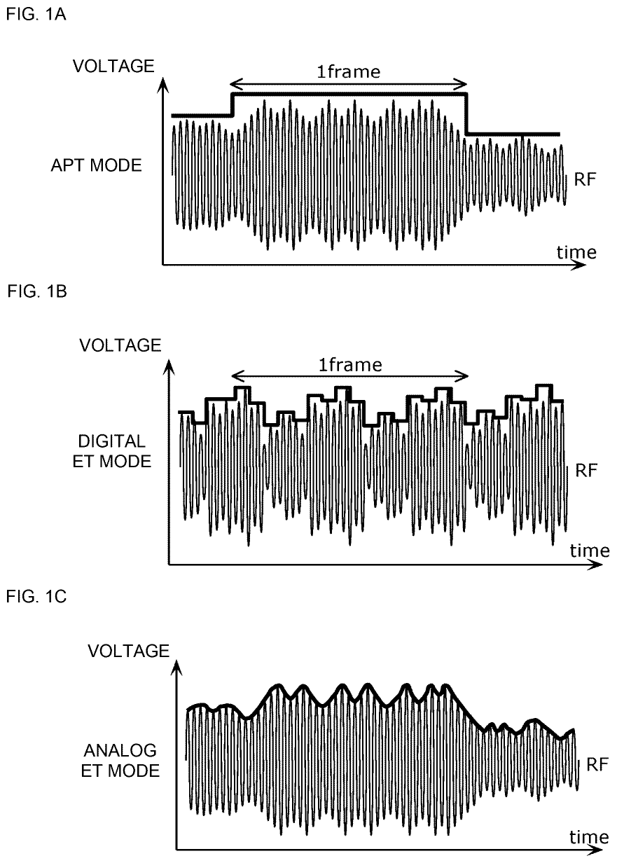

Tracking mode applied to voltage supplied to an amplifier circuit in the present embodiment will be described. Tracking mode is a mode for dynamically adjusting power supply voltage applied to a power amplifier circuit. Tracking mode has some types. In the present embodiment, an average power tracking (APT) mode, a digital envelope tracking (ET) mode, and an analog ET mode will be described by referring to FIGS. 1A to 1C. In FIGS. 1A to 1C, the horizontal axis represents time; the vertical axis represents voltage. A bold, solid line represents power supply voltage; a thin, solid line (waveform) represents a modulated signal.

FIG. 1A is a graph showing a transition example of power supply voltage in the APT mode. In the APT mode, the power supply voltage is changed among multiple discrete voltage levels in each frame on the basis of the average power. That is, in the APT mode, multiple discrete voltages are supplied in units of one frame.

For purposes of this disclosure, the term “frame” means a unit with which a radio frequency signal (modulated signal) is formed, and is defined in advance by a standardizing body (for example, 3GPP® (3rd Generation Partnership Project), and IEEE (Institute of Electrical and Electronics Engineers)). For example, in 5GNR (5th Generation New Radio) and LTE (Long Term Evolution), a frame contains ten subframes. Each subframe contains multiple slots. Each slot can be formed by multiple symbols. Each symbol may contain a cyclic prefix (CP). For example, the symbol length is 71 μs; the slot length is 0.5 ms; the subframe length is 1 ms; the frame length is 10 ms.

In the present embodiment, a mode in which the voltage level is changed in units of one frame or larger units on the basis of the average power is called the APT mode, and is differentiated from a mode in which the voltage level is changed in units smaller than a frame (for example, a subframe, a slot, or a symbol). For example, the mode in which the voltage level is changed in units of a symbol is called a symbol power tracking (SPT) mode and is differentiated from the APT mode.

FIG. 1B is a graph showing a transition example of power supply voltage in the digital ET mode. In the digital ET mode, the power supply voltage is changed among multiple discrete voltage levels within one frame on the basis of an envelope signal. That is, in the digital ET mode, multiple discrete voltages are supplied within one frame.

The envelope signal is a signal indicating the envelope of a modulated signal. The envelope value is expressed, for example, by the square root of (I²+Q²). (I, Q) represents a constellation point. A constellation point is a point indicating a modulated signal, which is obtained through digital modulation, on a constellation diagram. (I, Q) is defined by a BBIC 4, for example, on the basis of information about transmission.

Typically, fast switching among the discrete voltages in the digital ET mode may cause high-frequency noise, especially ringing, whose amount is larger than that in the APT mode, resulting in degradation of the PAE and the quality of a transmission signal.

FIG. 1C is a graph showing a transition example of power supply voltage in the analog ET mode. In the analog ET mode, the power supply voltage is changed continuously on the basis of the envelope signal. That is, in the analog ET mode, a continuous voltage is supplied.

Typically, in the analog ET mode, a DC-DC convertor, which is capable of variable output, is used. Therefore, when the envelope of a modulated signal changes at a high rate, it is difficult to cause the power supply voltage to follow the envelope.

### 1.2 Circuit Configuration

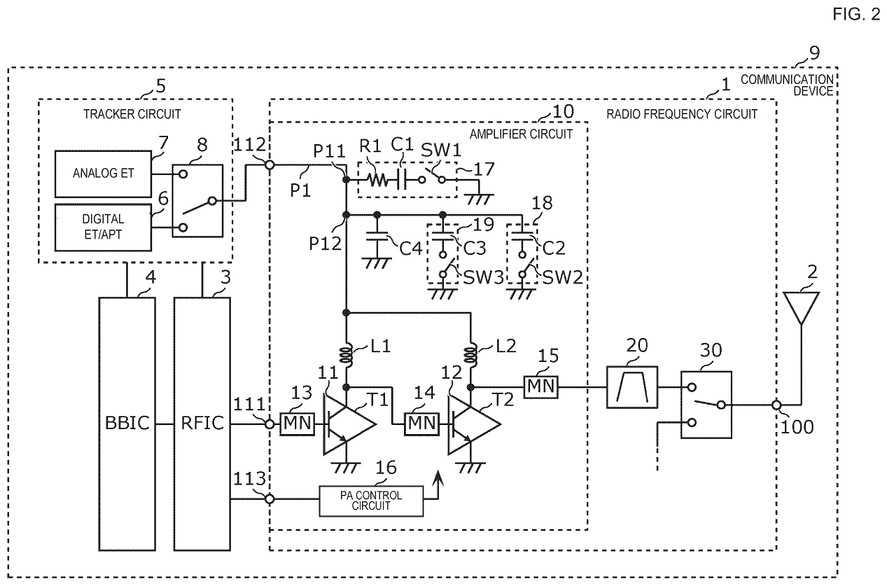

The circuit configuration of a communication device 9, a radio frequency circuit 1, and an amplifier circuit 10 according to the present embodiment will be described by referring to FIG. 2. FIG. 2 is a diagram illustrating the circuit configuration of the communication device 9 according to the present embodiment.

### 1.2.1 The Circuit Configuration of the Communication Device

The circuit configuration of the communication device 9 will be described. As illustrated in FIG. 2, the communication device 9 according to the present embodiment includes the radio frequency circuit 1, an antenna 2, an RFIC (Radio Frequency Integrated Circuit) 3, the BBIC (Baseband Integrated Circuit) 4, and a tracker circuit 5.

The radio frequency circuit 1 transports radio frequency signals between the antenna 2 and the RFIC 3. The internal configuration of the radio frequency circuit 1 will be described below.

The antenna 2, which is connected to an antenna connection terminal 100 of the radio frequency circuit 1, transmits radio frequency signals which are output from the radio frequency circuit 1. The antenna 2 may receive radio frequency signals from the outside for output to the radio frequency circuit 1.

The RFIC 3 is an exemplary signal processing circuit which processes radio frequency signals. Specifically, the RFIC 3 performs signal processing such as upconverting on transmission signals received from the BBIC 4, and outputs the radio-frequency transmission signals, which have been generated through the signal processing, to a transmission path of the radio frequency circuit 1. Further, the RFIC 3 may perform signal processing such as down-converting on radio-frequency receive signals received through a receive path of the radio frequency circuit 1, and may output, to the BBIC 4, the receive signals, which have been generated through the signal processing. In addition, the RFIC 3 has a controller which controls the radio frequency circuit 1 and the tracker circuit 5. Some or all of the functions as the controller of the RFIC 3 may be implemented in the outside of the RFIC 3, or may be implemented, for example, in the BBIC 4 or the radio frequency circuit 1.

The BBIC 4 is a baseband signal processing circuit which performs signal processing by using an intermediate frequency band having a frequency lower than that of radio frequency signals transported by the radio frequency circuit 1. For example, signals processed by the BBIC 4 are image signals for image display and/or audio signals for calls through speakers.

The tracker circuit 5 supplies a power supply voltage to the radio frequency circuit 1. In this example, the tracker circuit 5 is configured to supply voltages in the analog ET mode, the digital ET mode, and the APT mode, and includes a digital envelope tracker (digital ET)/average power tracker (APT) 6, an analog envelope tracker (analog ET) 7, and a mode switch 8.

The digital ET/APT 6 is configured to supply a power supply voltage to the amplifier circuit 10 in the digital ET mode or the APT mode. For example, the digital ET/APT 6 prepares in advance multiple discrete voltages, and uses a switch (not illustrated) to select, for output, at least one voltage among the discrete voltages prepared in advance. Thus, the digital ET/APT 6 is configured to switch among the discrete voltages, which are supplied to the amplifier circuit 10, by using the switch.

For example, in the digital ET mode, the digital ET/APT 6 selects, within one frame, multiple discrete voltages, for output, on the basis of the envelope signal. For example, in the APT mode, the digital ET/APT 6 selects, in units of one frame or larger units, multiple discrete voltages, for output, on the basis of the average power.

The digital ET/APT 6 does not necessarily prepare in advance the discrete voltages, and does not necessarily select, for output, a voltage among the discrete voltages by using the switch. For example, the digital ET/APT 6 may generate, for output, multiple discrete voltages whenever needed according to an exemplary aspect.

The analog ET 7 is configured to supply a power supply voltage to the amplifier circuit 10 in the analog ET mode. Specifically, the analog ET 7 outputs a continuous voltage on the basis of the envelope signal.

The mode switch 8 is connected between the amplifier circuit 10 and the digital ET/APT 6 and between the amplifier circuit 10 and the analog ET 7. The mode switch 8 is configured to connect the amplifier circuit 10 selectively to the digital ET/APT 6 and the analog ET 7 on the basis of a control signal from the RFIC 3. Establishing a connection between the amplifier circuit 10 and the digital ET/APT 6 causes a power supply voltage to be supplied to the amplifier circuit 10 in the digital ET mode or the APT mode. Establishing a connection between the amplifier circuit 10 and the analog ET 7 causes a power supply voltage to be supplied to the amplifier circuit 10 in the analog ET mode.

The circuit configuration of the communication device 9 illustrated in FIG. 2 is exemplary and is not so limited to this configuration. For example, the communication device 9 does not include the antenna 2 and/or the BBIC 4 in an alternative aspect. For example, the communication device 9 may include multiple antennas.

### 1.2.2 The Circuit Configuration of the Radio Frequency Circuit 1

The circuit configuration of the radio frequency circuit 1 will be described. As illustrated in FIG. 2, the radio frequency circuit 1 includes the amplifier circuit 10, a filter 20, a switch 30, the antenna connection terminal 100, a radio-frequency input terminal 111, a power supply voltage terminal 112, and a control terminal 113. The components of the radio frequency circuit 1 will be described one by one.

The antenna connection terminal 100 is connected to the switch 30 in the radio frequency circuit 1 and is connected to the antenna 2 outside the radio frequency circuit 1. A radio frequency signal, which has been amplified by the amplifier circuit 10, is output to the antenna 2 through the antenna connection terminal 100. A radio frequency signal received by the antenna 2 may be input to the radio frequency circuit 1 through the antenna connection terminal 100.

The radio-frequency input terminal 111 is a terminal for receiving radio frequency signals from the outside of the radio frequency circuit 1. The radio-frequency input terminal 111 is connected to the RFIC 3 outside the radio frequency circuit 1 and is connected to a power amplifier 11 through a matching circuit 13 inside the amplifier circuit 10. Thus, radio frequency signals received from the RFIC 3 through the radio-frequency input terminal 111 are supplied to the power amplifier 11.

In an exemplary aspect, the power supply voltage terminal 112 is a terminal for receiving a power supply voltage from the tracker circuit 5. The power supply voltage terminal 112 is connected to the tracker circuit 5 outside the amplifier circuit 10 and is connected to power amplifiers 11 and 12 through inductors L1 and L2 inside the amplifier circuit 10. Thus, a power supply voltage received from the tracker circuit 5 through the power supply voltage terminal 112 is supplied to the power amplifiers 11 and 12.

The control terminal 113 is a terminal for transporting control signals. That is, the control terminal 113 is a terminal for receiving control signals from the outside of the amplifier circuit 10, and/or a terminal for supplying control signals to the outside of the amplifier circuit 10.

The amplifier circuit 10 is configured to amplify a radio frequency signal by using a voltage supplied from the tracker circuit 5. The internal configuration of the amplifier circuit 10 will be described below.

The filter 20 is connected between the amplifier circuit 10 and the antenna connection terminal 100. Specifically, the filter 20 is connected, at its first end, to the amplifier circuit 10. The filter 20 is connected, at its second end, to the antenna connection terminal 100 through the switch 30. The filter 20 is, for example, a bandpass filter, and has a passband including a predetermined band used in transmission.

The predetermined band is a frequency band for a communication system constructed by using radio access technology (RAT). In an exemplary aspect, the predetermined band is defined in advance by a standardizing body or the like (for example, 3GPP and IEEE). Examples of a communication system may include a 5GNR system, an LTE system, and a WLAN (Wireless Local Area Network) system.

The switch 30 is connected between the antenna connection terminal 100 and the filter 20. The switch 30 includes a terminal connected to the antenna connection terminal 100, and a terminal connected to the filter 20. The switch 30 may include a terminal connected to a filter (not illustrated) having a passband different from that of the filter 20. The switch 30 may include a terminal connected to a filter (not illustrated) for reception.

The radio frequency circuit 1 illustrated in FIG. 2 is exemplary, and is not limited to this configuration. For example, the switch 30 of radio frequency circuit 1 can be omitted in an alternative aspect. Further, the radio frequency circuit 1 does not necessarily include a receive path. In this case, the receive path may be connected to a receive filter, a low-noise amplifier, and the like. For example, the radio frequency circuit 1 may include multiple antenna connection terminals.

### 1.2.3 The Circuit Configuration of the Amplifier Circuit 10

The circuit configuration of the amplifier circuit 10 will be described. As illustrated in FIG. 2, the amplifier circuit 10 includes the power amplifiers 11 and 12, the inductors L1 and L2, matching circuits (matching network: MN) 13 to 15, a PA (Power Amplifier) control circuit 16, an RC series circuit 17, and bypass capacitor circuits 18 and 19. The components of the amplifier circuit 10 will be described below one by one.

The power amplifier 11 is configured to amplify radio frequency signals, which are received from the radio-frequency input terminal 111, for output to the power amplifier 12. Specifically, the power amplifier 11 is disposed in the upstream stage (driving stage) of the power amplifier 12 and includes an amplifier transistor T1.

In the present embodiment, the amplifier transistor T1 is a bipolar transistor having a base terminal, a collector terminal, and an emitter terminal. The base terminal of the amplifier transistor T1 is connected to the radio-frequency input terminal 111 through the matching circuit 13. The collector terminal of the amplifier transistor T1 is connected to the power supply voltage terminal 112 through the inductor L1 and is connected to the input end of the power amplifier 12 through the matching circuit 14. The emitter terminal of the amplifier transistor T1 is connected to the ground. The amplifier transistor T1 is not limited to a bipolar transistor. For example, the amplifier transistor T1 may be a field-effect transistor in an alternative aspect. In this case, the base terminal, the collector terminal, and the emitter terminal are read as a gate terminal, a drain terminal, and a source terminal.

The power amplifier 12 is configured to further amplify radio frequency signals, which have been amplified by the power amplifier 11, for output to the filter 20. Specifically, the power amplifier 12 is disposed in the downstream stage (power stage) of the power amplifier 11 and includes an amplifier transistor T2.

In the present embodiment, the amplifier transistor T2 is a bipolar transistor having a base terminal, a collector terminal, and an emitter terminal. The base terminal of the amplifier transistor T2 is connected to the output end of the power amplifier 11 through the matching circuit 14. The collector terminal of the amplifier transistor T2 is connected to the power supply voltage terminal 112 through the inductor L2 and is connected to the filter 20 through the matching circuit 15. The emitter terminal of the amplifier transistor T2 is connected to the ground. The amplifier transistor T2 is not limited to a bipolar transistor. For example, the amplifier transistor T2 may be a field-effect transistor in an alternative aspect. In this case, the base terminal, the collector terminal, and the emitter terminal are read as a gate terminal, a drain terminal, and a source terminal.

The inductor L1 is connected in series to a voltage supply path P1 between the power supply voltage terminal 112 and the power amplifiers 11 and 12 and is a so-called choke inductor. Specifically, the inductor L1 is connected, at one end, to the collector terminal of the amplifier transistor T1, and is connected, at the other end, to the power supply voltage terminal 112.

The inductor L2 is connected in series to the voltage supply path P1 and is a so-called choke inductor. Specifically, the inductor L2 is connected, at one end, to the collector terminal of the amplifier transistor T2, and is connected, at the other end, to the power supply voltage terminal 112.

The matching circuit 13, which includes, for example, an inductor and/or a capacitor, is connected between the radio-frequency input terminal 111 and the input end of the power amplifier 11. The matching circuit 13 is configured to match the impedance between the radio-frequency input terminal 111 and the power amplifier 11.

The matching circuit 14, which includes, for example, an inductor and/or a capacitor, is connected between the output end of the power amplifier 11 and the input end of the power amplifier 12. The matching circuit 14 is configured to match the impedance between the power amplifiers 11 and 12.

The matching circuit 15, which includes, for example, an inductor and/or a capacitor, is connected between the output end of the power amplifier 12 and the filter 20. The matching circuit 15 is configured to match the impedance between the power amplifier 12 and the filter 20.

The PA control circuit 16 is a power amplifier controller (PAC) which controls the power amplifiers 11 and 12. The PA control circuit 16 controls, for example, bias currents, which are supplied to the respective base terminals of the amplifier transistors T1 and T2. The PA control circuit 16 is not necessarily included in the amplifier circuit 10.

The RC series circuit 17 includes a resistor R1, a capacitor C1, and a switch SW1 which are connected in series between the voltage supply path P1 and the ground, and functions as an on/off switchable RC snubber. That is, the RC series circuit 17 in the ON state is configured to suppress a transient voltage in the voltage supply path P1.

The resistor R1 is connected between the voltage supply path P1 and the ground and is connected in series to the capacitor C1 and the switch SW1. In the present embodiment, the resistor R1 is connected between the voltage supply path P1 and the capacitor C1. That is, the resistor R1 is connected, at its first end, to the voltage supply path P1, and is connected, at its second end, to a first electrode of the capacitor C1.

The capacitor C1, which is an exemplary first capacitor, is connected between the voltage supply path P1 and the ground and is connected in series to the resistor R1 and the switch SW1. In the present embodiment, the capacitor C1 is connected between the resistor R1 and the switch SW1. That is, the capacitor C1 is connected, at its first electrode, to the second end of the resistor R1, and is connected, at its second electrode, to the switch SW1.

The switch SW1, which is an exemplary first switch, is connected between the voltage supply path P1 and the ground and is connected in series to the resistor R1 and the capacitor C1. In the present embodiment, the switch SW1 is connected between the capacitor C1 and the ground. That is, the switch SW1 includes a terminal connected to the capacitor C1, and a terminal connected to the ground. Switching between connection and non-connection between the two terminals causes switching between connection and non-connection between the voltage supply path P1 and the ground through the resistor R1 and the capacitor C1. Thus, the RC series circuit 17 may be switched between on and off.

More specifically, in the state in which multiple discrete voltages are supplied to the power amplifiers 11 and 12 within one frame on the basis of the digital ET mode, the switch SW1 connects the voltage supply path P1 to the ground through the resistor R1 and the capacitor C1. In contrast, in the state in which multiple discrete voltages are supplied to the power amplifiers 11 and 12 in units of one frame on the basis of the APT mode, and in the state in which a continuous voltage is supplied to the power amplifiers 11 and 12 on the basis of the analog ET mode, the switch SW1 does not connect the voltage supply path P1 to the ground through the resistor R1 and the capacitor C1.

The circuit configuration of the RC series circuit 17 illustrated in FIG. 2 is exemplary and is not limited to this configuration. For example, the connection order of the resistor R1, the capacitor C1, and the switch SW1 may be changed in alternative aspects. The switch SW1 may also be connected between the voltage supply path P1 and the resistor R1. For example, the switch SW1 is not necessarily included in the RC series circuit 17. The RC series circuit 17 is not necessarily on/off switchable. Multiple RC series circuits 17 may be connected in parallel to the voltage supply path P1.

The bypass capacitor circuit 18, which is an exemplary first bypass capacitor circuit, includes a capacitor C2 and a switch SW2 that are connected in series between the voltage supply path P1 and the ground, and functions as an on/off switchable bypass capacitor.

The capacitor C2, which is an exemplary second capacitor, is connected between the voltage supply path P1 and the ground and is connected in series to the switch SW2. In the present embodiment, the capacitor C2 is connected between the voltage supply path P1 and the switch SW2. That is, the capacitor C2 is connected, at its first electrode, to the voltage supply path P1, and is connected, at its second electrode, to the switch SW2.

The capacitor C2 has an electrostatic capacity, for example, of one microfarad. Thus, when multiple discrete voltages are supplied from the tracker circuit in units of one frame of a radio frequency signal or larger units, the capacitor C2 contributes stabilization of the voltages in the units. It is noted that the electrostatic capacity of the capacitor C2 is not limited to one microfarad, and may be changed appropriately, for example, in accordance with a requirement specification of the amplifier circuit 10.

The switch SW2, which is an exemplary second switch, is connected between the voltage supply path P1 and the ground and is connected in series to the capacitor C2. In the present embodiment, the switch SW2 is connected between the capacitor C2 and the ground. That is, the switch SW2 includes a terminal connected to the capacitor C2, and a terminal connected to the ground. Switching between connection and non-connection between the two terminals causes switching between connection and non-connection between the voltage supply path P1 and the ground through the capacitor C2. Thus, the bypass capacitor circuit 18 is switched between on and off.

More specifically, in the state in which multiple discrete voltages are supplied to the power amplifiers 11 and 12 on the basis of the APT mode in units of one frame or larger units, the switch SW2 connects the voltage supply path P1 to the ground through the capacitor C2. In the state in which multiple discrete voltages are supplied to the power amplifiers 11 and 12 within one frame on the basis of the digital ET mode, and in the state in which a continuous voltage is supplied to the power amplifiers 11 and 12 on the basis of the analog ET mode, the switch SW2 does not connect the voltage supply path P1 to the ground through the capacitor C2.

The bypass capacitor circuit 18 is connected between the ground and the voltage supply path P1 between the RC series circuit 17 and the power amplifiers 11 and 12. In other words, the bypass capacitor circuit 18 is connected to a point closer to the power amplifiers 11 and 12 on the voltage supply path P1 than the RC series circuit 17. That is, point P12 on the voltage supply path P1, where the bypass capacitor circuit 18 is connected, is closer to the power amplifiers 11 and 12 than point P11 on the voltage supply path P1, where the RC series circuit 17 is connected. Conversely, point P11 is closer to the tracker circuit 5 than point P12.

The positions, where the RC series circuit 17 and the bypass capacitor circuit 18 are connected to the voltage supply path P1, are not limited to these configurations. For example, the RC series circuit 17 may be connected to point P12, and the bypass capacitor circuit 18 may be connected to point P11 in an alternative aspect. In addition, for example, the RC series circuit 17 and the bypass capacitor circuit 18 may be connected to the same point (for example, one of points P11 and P12) in another alternative aspect.

The circuit configuration of the bypass capacitor circuit 18, which is illustrated in FIG. 2, is exemplary, and is not limited to this configuration. For example, the connection order of the capacitor C2 and the switch SW2 may be changed, and the switch SW2 may be connected between the voltage supply path P1 and the capacitor C2 in alternative aspects.

The bypass capacitor circuit 19, which is an exemplary second bypass capacitor circuit, includes a capacitor C3 and a switch SW3 which are connected in series between the voltage supply path P1 and the ground, and functions as an on/off switchable bypass capacitor.

The capacitor C3, which is an exemplary third capacitor, is connected between the voltage supply path P1 and the ground and is connected in series to the switch SW3. In the present embodiment, the capacitor C3 is connected between the voltage supply path P1 and the switch SW3. That is, the capacitor C3 is connected, at its first electrode, to the voltage supply path P1, and is connected, at its second electrode, to the switch SW3.

The capacitor C3 has an electrostatic capacity, for example, of 10 nanofarad. Thus, when multiple discrete voltages are supplied from the tracker circuit within one frame of a radio frequency signal, the capacitor C3 achieves a balance between stabilization of voltage and responsivity. The electrostatic capacity of the capacitor C3 is not limited to 10 nanofarad, and may be changed appropriately, for example, in accordance with a requirement specification of the amplifier circuit 10.

The switch SW3, which is an exemplary third switch, is connected between the voltage supply path P1 and the ground and is connected in series to the capacitor C3. In the present embodiment, the switch SW3 is connected between the capacitor C3 and the ground. That is, the switch SW3 includes a terminal connected to the capacitor C3, and a terminal connected to the ground. Switching between connection and non-connection among the two terminals causes switching between connection and non-connection between the voltage supply path P1 and the ground through the capacitor C3. Thus, the bypass capacitor circuit 18 is switched between on and off.

More specifically, in the state in which multiple discrete voltages are supplied to the power amplifiers 11 and 12 on the basis of the APT mode in units of one frame or larger units, and in the state in which multiple discrete voltages are supplied to the power amplifiers 11 and 12 within one frame on the basis of the digital ET mode, the switch SW3 connects the voltage supply path P1 to the ground through the capacitor C3. In the state in which a continuous voltage is supplied to the power amplifiers 11 and 12 on the basis of the analog ET mode, the switch SW3 does not connect the voltage supply path P1 to the ground through the capacitor C3.

In the exemplary aspect, the bypass capacitor circuit 19 is connected between the ground and the voltage supply path P1 between the RC series circuit 17 and the power amplifiers 11 and 12. In other words, the bypass capacitor circuit 19 is connected to a point closer to the power amplifiers 11 and 12 on the voltage supply path P1 than the RC series circuit 17. That is, point P12 on the voltage supply path P1, where the bypass capacitor circuit 19 is connected, is closer to the power amplifiers 11 and 12 than point P11 on the voltage supply path P1, where the RC series circuit 17 is connected. Conversely, point P11 is closer to the tracker circuit 5 than point P12.

The points, where the RC series circuit 17 and the bypass capacitor circuit 19 are connected to the voltage supply path P1, are not limited to these configurations. For example, the RC series circuit 17 may be connected to point P12, and the bypass capacitor circuit 19 may be connected to point P11. In addition, for example, the RC series circuit 17 and the bypass capacitor circuit 19 may be connected to the same point (for example, one of points P11 and P12).

The circuit configuration of the bypass capacitor circuit 19, which is illustrated in FIG. 2, is exemplary, and is not limited to this configuration. For example, the connection order of the capacitor C3 and the switch SW3 may be changed, and the switch SW3 may be connected between the voltage supply path P1 and the capacitor C3 in alternative aspects. In addition, for example, the switch SW3 is not necessarily included in the bypass capacitor circuit 19.

A capacitor C4, which is an exemplary fourth capacitor, is configured to function as a bypass capacitor. The capacitor C4 is connected between the voltage supply path P1 and the ground. That is, the capacitor C4 has two electrodes connected to the voltage supply path P1 and the ground, respectively.

According to an exemplary aspect, the capacitor C4 has an electrostatic capacity, for example, of 100picofarad. Thus, when a continuous voltage is supplied from the tracker circuit on the basis of the analog ET mode, the capacitor C4 achieves suppression of reduction of responsivity. It is noted that the electrostatic capacity of the capacitor C4 is not limited to 100 picofarad, and may be changed appropriately, for example, in accordance with a requirement specification of the amplifier circuit 10.

The electrostatic capacities of the capacitors C1 to C4 may be measured by using an LCR meter in an exemplary aspect. At that time, an auto-balancing bridge method may be used as a measurement method.

It is noted that in the amplifier circuit 10 according to the present embodiment, the bypass capacitor circuits 18 and 19, the inductors L1 and L2, the capacitor C4, and the matching circuits 13 to 15 may be appropriately omitted or replaced with other circuit devices, for example, in accordance with a requirement specification of the amplifier circuit 10, and are not components according to other exemplary aspects. For example, when the tracker circuit 5 is configured for supplying only a power supply voltage based on the digital ET mode, the bypass capacitor circuit 18 and the capacitor C4 are not necessarily included in the amplifier circuit 10, and the switches SW1 and SW3 are not necessarily included in the RC series circuit 17 and the bypass capacitor circuit 19.

Moreover, an inductor, a capacitor, or a resistor may be added in the amplifier circuit 10 according to exemplary aspects. For example, an inductor may be added between the ground and the emitter terminals of the amplifier transistors T1 and/or T2.

One of the power amplifiers 11 and 12 is not necessarily included in the amplifier circuit 10. In addition to the power amplifiers 11 and 12, the amplifier circuit 10 may further include at least one power amplifier.

In this case, the at least one power amplifier may be connected to the power amplifier 11 or 12 continuously, or may be connected in parallel to the power amplifier 11 or 12.

### 1.3 Amplifying Method

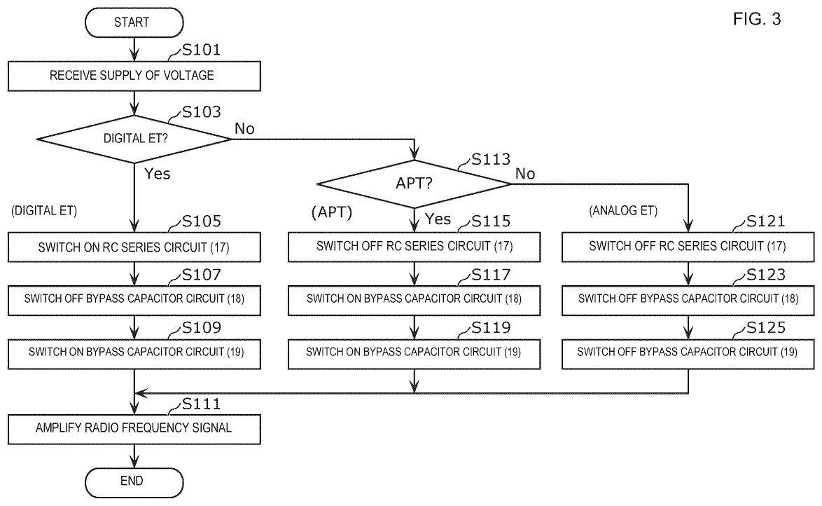

A method of amplifying a radio frequency signal, which is performed by the amplifier circuit 10 having such a configuration described above, will be described by referring to FIG. 3. FIG. 3 is a flowchart of an amplifying method according to the present embodiment.

The amplifier circuit 10 receives supply of a voltage from the tracker circuit 5 (S101).

If the voltage received in step S101 is a power supply voltage based on the digital ET mode (Yes in S103), the RC series circuit 17 is switched on (S105). Specifically, the switch SW1 connects the voltage supply path P1 to the ground through the resistor R1 and the capacitor C1. Thus, in the state in which multiple discrete voltages are received within one frame of a radio frequency signal, the amplifier circuit 10 may attenuate ringing of the discrete voltages by using the RC series circuit 17. Further, the bypass capacitor circuit 18 is switched off (S107), and the bypass capacitor circuit 19 is switched on (S109).

If the voltage received in step S101 is a power supply voltage based on the APT mode (No in S103 and Yes in S113), the RC series circuit 17 is switched off (S115). Specifically, the switch SW1 does not connect the voltage supply path P1 to the ground through the resistor R1 and the capacitor C1. Thus, in the state in which multiple discrete voltages are received in units of one frame of a radio frequency signal or larger units, the amplifier circuit 10 may prohibit use of the RC series circuit 17. Further, the bypass capacitor circuit 18 is switched on (S117), and the bypass capacitor circuit 19 is switched on (S119).

If the voltage received in step S101 is a power supply voltage based on the analog ET mode (No in S103 and No in S113), the RC series circuit 17 is switch off (S121). Specifically, the switch SW1 does not connect the voltage supply path P1 to the ground through the resistor R1 and the capacitor C1. Thus, in the state in which a continuous voltage is received, the amplifier circuit 10 may prohibit use of the RC series circuit 17. Further, the bypass capacitor circuit 18 is switched off (S123), and the bypass capacitor circuit 19 is switched off (S125).

Finally, the amplifier circuit 10 amplifies the radio frequency signal by using the supplied voltage (S111).

It is noted that the amplifying method illustrated in FIG. 3 is exemplary. The steps, the order of steps, and the like are not limited to these. For example, when a voltage is supplied from the tracker circuit 5 only on the basis of the digital ET mode, not on the basis of the APT mode and the analog ET mode, steps S103, S107, S109, and S113 to S125 may be skipped, as long as, in step S105, ringing of multiple discrete voltages may be attenuated by using the RC series circuit 17.

### 1.4 The Component Layout of a Radio Frequency Module 1M

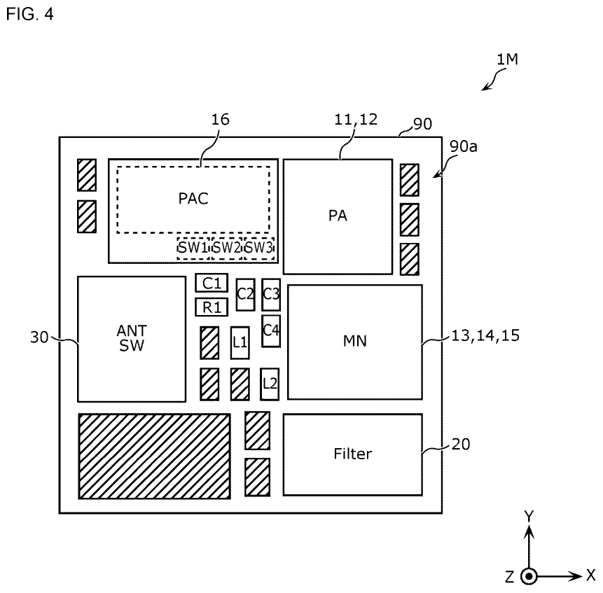

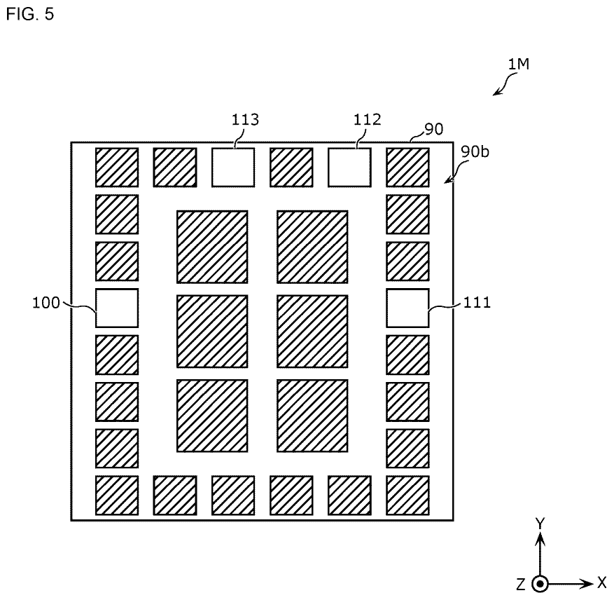

A radio frequency module 1M will be described as an implementation example of the radio frequency circuit 1, having such a configuration described above, by referring to FIGS. 4 and 5.

FIG. 4 is a plan view of the radio frequency module 1M according to the present embodiment. FIG. 5 is a plan view of the radio frequency module 1M according to the present embodiment and is a see-through view of the principal surface 90b side of a module substrate 90 from the z-axis positive side.

In FIGS. 4 and 5, wiring, which connects multiple circuit components disposed on the module substrate 90, is not illustrated. In FIGS. 4 and 5, a hatched block represents an optional circuit component or electromechanical component, which can be omitted in an exemplary aspect. In FIGS. 4 and 5, to easily understand the layout relationship of the components, each component has characters which are illustrated thereon, and which represent its embedded circuit or device. However, such characters are not necessarily illustrated on each actual component.

The radio frequency module 1M includes the module substrate 90, on which the amplifier circuit 10, the filter 20, the switch 30, the antenna connection terminal 100, the radio-frequency input terminal 111, the power supply voltage terminal 112, and the control terminal 113, which are illustrated in FIG. 2, are disposed.

The module substrate 90 has principal surfaces 90a and 90b which are opposite each other. Via conductors, wiring, ground electrode layers, and the like are formed in the module substrate 90 and on the principal surface 90a. In FIGS. 4 and 5, the module substrate 90 is rectangular in plan view, but the shape is not limited to this configuration.

In exemplary aspects, the module substrate 90 may be, for example, a low temperature co-fired ceramics (LTCC) substrate or a high temperature co-fired ceramics (HTCC) substrate, which has a multilayer structure of multiple dielectric layers, a component-embedded board, a substrate having a redistribution layer (RDL), a printed circuit board, or the like, but is not so limited.

On the principal surface 90a, the power amplifiers 11 and 12 (PA), the matching circuits 13 to 15 (MN), and an integrated circuit, which includes the PA control circuit 16 (PAC) and the switches SW1 to SW3, the capacitors C1 to C4, the inductors L1 and L2, the resistor R1, the filter 20 (Filter), and the switch 30 (ANT SW) are disposed.

The integrated circuit, which includes the PA control circuit 16 and the switches SW1 to SW3, is formed, for example, by using CMOS (Complementary Metal Oxide Semiconductor), and, specifically, may be manufactured through an SOI (Silicon on Insulator) process. The integrated circuit is not limited to CMOS.

In an exemplary aspect, each of the capacitors C1 to C4 is implemented as a chip capacitor. A chip capacitor refers to a surface mount device (SMD) forming a capacitor. It is noted that implementation of the capacitors C1 to C4 is not limited to chip capacitors. For example, some or all of the capacitors C1 to C4 may be included in an integrated passive device (IPD) or may be included in an integrated circuit in alternative aspects.

Moreover, each of the inductors L1 and L2 is implemented as a chip inductor. A chip inductor refers to an SMD forming an inductor. However, implementation of the inductors L1 and L2 is not limited to chip inductors. For example, the inductors L1 and L2 may be included in an IPD in alternative aspects.

According to an exemplary aspect, the resistor R1 is implemented as a chip resistor. A chip resistor refers to an SMD forming a resistor. However, implementation of the resistor R1 is not limited to a chip resistor. For example, the resistor R1 may be included in an IPD in alternative aspects.

On the principal surface 90b, in addition to the antenna connection terminal 100, the radio-frequency input terminal 111, the power supply voltage terminal 112, and the control terminal 113, multiple external connection terminals including ground terminals are disposed. Each of the external connection terminals is connected, for example, to an input/output terminal and/or a ground terminal on a mother board (not illustrated) disposed in the z-axis negative direction of the radio frequency module 1M. The external connection terminals may be, for example, copper electrodes and solder electrodes.

The configuration of the radio frequency module 1M illustrated in FIGS. 4 and 5 is exemplary and is not limited to this configuration. For example, some or all of the circuit components disposed on the principal surface 90a may be formed in the module substrate 90. Some of the circuit components disposed on the principal surface 90a are not necessarily included in the radio frequency module 1M and are not necessarily disposed on the module substrate 90. For example, the radio frequency module 1M does not necessarily include the filter 20 and the switch 30 in an alternative aspect. In this case, the radio frequency module 1M is called an amplifier module. The radio frequency module 1M can include a resin member which covers the components on the principal surface 90a and can further include a shield electrode layer that covers the resin member.

### 1.5 Effects and the Like

As described above, the amplifier circuit 10 according to the present embodiment is configured to amplify a radio frequency signal by using multiple discrete voltages supplied from the tracker circuit 5 within one frame of the radio frequency signal. The amplifier circuit 10 includes the power amplifier 12 and the RC series circuit 17 which includes the resistor R1 and the capacitor C1 which are connected in series between the ground and the voltage supply path P1 between the tracker circuit 5 and the power amplifier 12.

According to this configuration, when multiple discrete voltages are supplied within one frame of a radio frequency signal, high-frequency noise, especially ringing, contained in the discrete voltages may be attenuated by the RC series circuit 17. Therefore, the quality of a radio frequency signal amplified by using the discrete voltages is improved. In particular, in the case of switching among multiple discrete voltages within one frame, the frequency of occurrence of ringing is high. Thus, the RC series circuit 17 has a large noise attenuation effect.

In addition, for example, the amplifier circuit 10 according to the present embodiment may further include the bypass capacitor circuit 18 that includes the capacitor C2 connected between the voltage supply path P1 and the ground.

According to this configuration, high-frequency noise contained in the discrete voltages may be further attenuated.

The amplifier circuit 10 according to the present embodiment includes the power amplifier 12, the RC series circuit 17 that includes the resistor R1 and the capacitor C1 which are connected in series between the ground and the voltage supply path P1 for the power amplifier 12, and the bypass capacitor circuit 18 that includes the capacitor C2 connected between the ground and the voltage supply path P1.

According to this configuration, high-frequency noise, which is contained in the power supply voltage supplied through the voltage supply path P1 to the power amplifier 12, may be attenuated by the RC series circuit 17 and the bypass capacitor circuit 18. For example, when multiple discrete voltages are supplied to the amplifier circuit 10 in the digital ET mode, ringing may be attenuated by the RC series circuit 17 and the bypass capacitor circuit 18, and the quality of a radio frequency signal amplified by the amplifier circuit 10 is improved.

In addition, for example, in the amplifier circuit 10 according to the present embodiment, the resistor R1 of the RC series circuit 17 may be connected between the capacitor C1 of the RC series circuit 17 and the voltage supply path P1.

According to this configuration, the resistor R1 is connected to the voltage supply path P1 not through the capacitor C1. Thus, the resistor R1 may more effectively change, for absorption, the high-frequency noise into heat.

In addition, for example, in the amplifier circuit 10 according to the present embodiment, the RC series circuit 17 may further include the switch SW1 connected in series to the resistor R1 and the capacitor C1.

According to this configuration, the switch SW1 can be configured to switch between connection and non-connection of the voltage supply path P1 to the ground through the resistor R1 and the capacitor C1. Therefore, for example, the switch SW1 switched off in the analog ET mode enables suppression of degradation of responsivity which is caused by the RC series circuit 17. In addition, for example, the switch SW1 switched off in the APT mode enables suppression of a reduction of the power supply voltage that is caused by the RC series circuit 17.

In addition, for example, in the amplifier circuit 10 according to the present embodiment, the switch SW1 may be connected between the ground and the resistor R1 and the capacitor C1.

According to this configuration, when the switch SW1 is formed by a field-effect transistor, the source of the field-effect transistor may be connected to the ground. Therefore, when a voltage is applied to the gate of the field-effect transistor to switch on the switch SW1, the gate-source potential difference may be made high. As a result, the drain-source impedance may be reduced, achieving more effective operation of the RC series circuit 17.

In addition, for example, in the amplifier circuit 10 according to the present embodiment, in the state in which the discrete voltages are supplied to the power amplifier 12 on the basis of the digital ET mode, the switch SW1 may connect the voltage supply path P1 to the ground through the resistor R1 and the capacitor C1. In the state in which the discrete voltages are supplied to the power amplifier 12 on the basis of the APT mode, the switch SW1 does not necessarily connect the voltage supply path P1 to the ground through the resistor R1 and the capacitor C1.

According to this configuration, in the digital ET mode, the voltage supply path P1 is connected to the ground through the resistor R1 and the capacitor C1. Therefore, the RC series circuit 17 may attenuate ringing, and the quality of a radio frequency signal amplified by the power amplifier 12 is improved. In the APT mode, the voltage supply path P1 is not connected to the ground through the resistor R1 and the capacitor C1. Therefore, a decrease of voltage, which is caused by the RC series circuit 17, is suppressed, improving the efficiency.

In addition, for example, in the amplifier circuit 10 according to the present embodiment, in the state in which a continuous voltage is supplied to the power amplifier 12 on the basis of the analog ET mode, the switch SW1 does not necessarily connect the voltage supply path P1 to the ground through the resistor R1 and the capacitor C1.

According to this configuration, in the analog ET mode, the voltage supply path P1 is not connected to the ground through the resistor R1 and the capacitor C1. Therefore, degradation of responsivity, which is caused by the RC series circuit 17, is suppressed, and reduction of the tracking performance of the power supply voltage following the envelope of a radio frequency signal is also suppressed.

In addition, for example, in the amplifier circuit 10 according to the present embodiment, the bypass capacitor circuit 18 may be connected between the ground and the voltage supply path P1 between the RC series circuit 17 and the power amplifier 12.

According to this configuration, the length of wiring between the bypass capacitor circuit 18 and the power amplifier 12 may be reduced, and the impedance, especially inductance, of the wiring between the bypass capacitor circuit 18 and the power amplifier 12 is suppressed. As a result, degradation of characteristics of the bypass capacitor, which is caused by an increase of impedance of the wiring between the bypass capacitor circuit 18 and the power amplifier 12, is also suppressed, achieving improvement of the noise reduction effect.

In addition, for example, in the amplifier circuit 10 according to the present embodiment, the bypass capacitor circuit 18 may further include the switch SW2 connected between the capacitor C2 and the voltage supply path P1 or the ground.

According to this configuration, the switch SW2 can be configured to switch between connection and non-connection of the voltage supply path P1 to the ground through the capacitor C2. Therefore, the bypass capacitor may be switched between on and off in accordance with the type of the tracking mode. As a result, a bypass capacitor configured for the tracking mode may be operated. For example, in the APT mode, connection of the voltage supply path P1 to the ground through the capacitor C2 achieves reduction of noise and stabilization of the voltage by using the capacitor C2. In addition, for example, in the digital ET mode and the analog ET mode, non-connection of the voltage supply path P1 to the ground through the capacitor C2 achieves suppression of reduction of responsivity, which is caused by the capacitor C2.

In addition, for example, in the amplifier circuit 10 according to the present embodiment, the switch SW2 may be connected between the capacitor C2 and the ground.

According to this configuration, when the switch SW2 is formed by a field-effect transistor, the source of the field-effect transistor may be connected to the ground. Therefore, when a voltage is applied to the gate of the field-effect transistor to switch on the switch SW2, the gate-source potential difference may be increased. As a result, the drain-source impedance may be reduced, achieving more effective operation of the bypass capacitor circuit 18.

In addition, for example, in the amplifier circuit 10 according to the present embodiment, in the state in which the discrete voltages are supplied to the power amplifier 12 on the basis of the digital ET mode, the switch SW2 does not necessarily connect the voltage supply path P1 to the ground through the capacitor C2. In the state in which the discrete voltages are supplied to the power amplifier 12 on the basis of the APT mode, the switch SW2 may connect the voltage supply path P1 to the ground through the capacitor C2.

According to this configuration, in the APT mode, the voltage supply path P1 is connected to the ground through the capacitor C2. Therefore, reduction of noise and stabilization of the voltage is achieved by using the capacitor C2, and reduction of the PAE and reduction of the quality of a radio frequency signal is suppressed in the APT mode. In the digital ET mode, the voltage supply path P1 is not connected to the ground through the capacitor C2. Therefore, reduction of responsivity, which is caused by the capacitor C2, is suppressed, and reduction of the tracking performance in the digital ET mode is also suppressed.

In addition, for example, in the amplifier circuit 10 according to the present embodiment, in the state in which a continuous voltage is supplied to the power amplifier 12 on the basis of the analog ET mode, the switch SW2 does not necessarily connect the voltage supply path P1 to the ground through the capacitor C2.

According to this configuration, in the analog ET mode, the voltage supply path P1 is not connected to the ground through the capacitor C2. Therefore, reduction of responsivity, which is caused by the capacitor C2, is suppressed, and reduction of the tracking performance in the analog ET mode is also suppressed.

In addition, for example, the amplifier circuit 10 according to the present embodiment may further include the bypass capacitor circuit 19 including the capacitor C3 connected in series between the voltage supply path P1 and the ground. In this aspect, the capacitor C3 may have an electrostatic capacity smaller than that of the capacitor C2.

According to this configuration, the capacitor C3, which has an electrostatic capacity smaller than that of the capacitor C2, may be used as a bypass capacitor, enabling use of a bypass capacitor suitable for the tracking mode.

In addition, for example, in the amplifier circuit 10 according to the present embodiment, the bypass capacitor circuit 19 may be connected between the ground and the voltage supply path P1 between the RC series circuit 17 and the power amplifier 12.

According to this configuration, the length of wiring between the bypass capacitor circuit 19 and the power amplifier 12 may be reduced, and the impedance, especially inductance, of the wiring between the bypass capacitor circuit 19 and the power amplifier 12 is suppressed. As a result, degradation of characteristics of the bypass capacitor, which is caused by an increase of the impedance of the wiring between the bypass capacitor circuit 19 and the power amplifier 12, is suppressed, achieving improvement of the noise reduction effect.

In addition, for example, in the amplifier circuit 10 according to the present embodiment, the bypass capacitor circuit 19 may further include the switch SW3 connected between the capacitor C3 and the voltage supply path P1 or the ground. The amplifier circuit 10 may further include the capacitor C4 connected between the voltage supply path P1 and the ground. The capacitor C4 may have an electrostatic capacity smaller than that of each of the capacitor C2 and the capacitor C3.

According to this configuration, a combination of the capacitors C2 to C4, having electrostatic capacities different from each other, may be used as a bypass capacitor, achieving the electrostatic capacity of the bypass capacitor that is suitable for the tracking mode.

In addition, for example, in the amplifier circuit 10 according to the present embodiment, the switch SW3 may be connected between the capacitor C3 and the ground.

According to this configuration, when the switch SW3 is formed by a field-effect transistor, the source of the field-effect transistor may be connected to the ground. Therefore, when a voltage is applied to the gate of the field-effect transistor to switch on the switch SW3, the gate-source potential difference may be increased. As a result, the drain-source impedance may be reduced, achieving more effective operation of the bypass capacitor circuit 19.

In addition, for example, in the amplifier circuit 10 according to the present embodiment, in the state in which the discrete voltages are supplied to the power amplifier 12 on the basis of the digital ET mode and the APT mode, the switch SW3 may connect the voltage supply path P1 to the ground through the capacitor C3. In the state in which a continuous voltage is supplied to the power amplifier 12 on the basis of the analog ET mode, the switch SW3 does not necessarily connect the voltage supply path P1 to the ground through the capacitor C3.

According to this configuration, in the digital ET mode and the APT mode, the voltage supply path P1 is connected to the ground through the capacitor C3. Therefore, reduction of noise and stabilization of voltage is achieved by using the capacitor C3, and reduction of the PAE and reduction of the quality of a radio frequency signal is suppressed in the digital ET mode and the APT mode. In the analog ET mode, the voltage supply path P1 is not connected to the ground through the capacitor C3. Therefore, reduction of responsivity, which is caused by the capacitor C3, is suppressed, and reduction of the tracking performance in the analog ET mode is also suppressed.

In addition, the amplifying method according to the present embodiment is a method for amplifying a radio frequency signal. In the method, supply of multiple discrete voltages within one frame of the radio frequency signal is received; ringing of the discrete voltages is attenuated by using the RC series circuit 17; the radio frequency signal is amplified by using the discrete voltages whose ringing has been attenuated.

According to this configuration, when multiple discrete voltages are supplied within one frame of a radio frequency signal, ringing contained in the discrete voltages may be attenuated by using the RC series circuit 17. Therefore, the quality of a radio frequency signal amplified by using the discrete voltages is improved. In particular, when switching among multiple discrete voltages within one frame, the frequency of occurrence of ringing is high. Thus, the RC series circuit 17 has a large noise attenuation effect.

In addition, for example, in the amplifying method according to the present embodiment, supply of the discrete voltages may be further received in units of one frame of a radio frequency signal or larger units. In the state in which supply of the discrete voltages is received within one frame of a radio frequency signal, ringing of the discrete voltages may be attenuated by using the RC series circuit 17. In the state in which supply of the discrete voltages is received in units of one frame of a radio frequency signal or larger units, ringing of the discrete voltages is not necessarily attenuated by using the RC series circuit 17.

According to this configuration, in the state, in which multiple discrete voltages are supplied within one frame and in which the frequency of occurrence of ringing is high, the RC series circuit 17 can be configured to attenuate ringing, and the quality of a radio frequency signal may be improved. In contrast, in the state, in which multiple discrete voltages are supplied in units of one frame or larger units and in which the frequency of occurrence of ringing is low, the RC series circuit 17 is not used, achieving suppression, for example, of a voltage decrease caused by the RC series circuit 17.

### ADDITIONAL EXEMPLARY EMBODIMENTS

The amplifier circuit and the amplifying method provided by the present disclosure are described on the basis of the exemplary embodiment. However, it is noted that the exemplary amplifier circuit and the amplifying method are not limited to the embodiment. A different embodiment, which is implemented by using a combination of any components in the embodiment, a modified example, which is obtained by making, on the embodiment, various modifications conceived by those skilled in the art without departing from the gist of the present disclosure, various devices, which include the amplifier circuit, are encompassed in the present disclosure.

For example, in the circuit configuration of the amplifier circuit, the radio frequency circuit, and the communication device according to the embodiment, a different circuit device, wiring, and the like may be added on a path connecting a circuit device and a signal path, which are disclosed in the drawings. For example, a filter and/or a matching circuit may be added between the switch 30 and the antenna connection terminal 100.

In the embodiment, the tracker circuit 5 is compatible with the analog ET mode, the digital ET mode, and the APT mode. However, the configuration is not so limited. For example, the tracker circuit 5 may be compatible only with the digital ET mode. In this case, the tracker circuit 5 does not necessarily include the analog ET 7 and the mode switch 8. Further, the amplifier circuit 10 does not necessarily include the bypass capacitor circuit 18, and the RC series circuit 17 and the bypass capacitor circuit 19 do not necessarily include the switches SW1 and SW3. In addition, for example, the tracker circuit 5 may be compatible only with the digital ET mode and the APT mode. In this case, the tracker circuit 5 does not necessarily include the analog ET 7 and the mode switch 8. Further, the bypass capacitor circuit 19 does not necessarily include the switch SW3.

It should be appreciated that the modes supported by the tracker circuit 5 are not limited to the analog ET mode, the digital ET mode, and the APT mode. For example, the tracker circuit 5 may be compatible with the SPT mode. In the SPT mode, the amplifier circuit 10 may perform substantially the same processing as that in the digital ET mode. That is, in the SPT mode, the amplifier circuit 10 switches on the switch SW1; switches off the switch SW2; and switches on the switch SW3, achieving improvement of the radio-frequency signal amplification characteristics.

In the embodiment described above, the bypass capacitor circuits 18 and 19 are switched between on and off in accordance with the type of the tracking mode. However, the configuration is not so limited. For example, the bypass capacitor circuits 18 and 19 may be switched between on and off in accordance with the channel bandwidth of a radio frequency signal in an alternative aspect.

The features of the tracker circuit, the tracker module, and the voltage supply method described on the basis of the exemplary embodiments will be described.

<1> An amplifier circuit configured to amplify a radio frequency signal by using a plurality of discrete voltages supplied from a tracker circuit within one frame of the radio frequency signal, the amplifier circuit comprising: a power amplifier; and an RC series circuit that includes a resistor and a first capacitor which are connected in series between a ground and a voltage supply path between the tracker circuit and the power amplifier.

<2> The amplifier circuit according to <1>, further comprising: a first bypass capacitor circuit that includes a second capacitor connected between the voltage supply path and the ground.

<3> An amplifier circuit comprising: a power amplifier; an RC series circuit that includes a resistor and a first capacitor which are connected in series between a ground and a voltage supply path for the power amplifier; and a first bypass capacitor circuit that includes a second capacitor connected between the ground and the voltage supply path.

<4> The amplifier circuit according to any one of <1> to <3>, wherein, in the RC series circuit, the resistor is connected between the first capacitor and the voltage supply path.

<5> The amplifier circuit according to any one of <1> to <4>, wherein the RC series circuit further includes a first switch connected in series to the resistor and the first capacitor.

<6> The amplifier circuit according to <5>, wherein the first switch is connected between the ground, and the resistor and the first capacitor.

<7> The amplifier circuit according to <5> or <6>, wherein, in a state in which the plurality of discrete voltages are supplied to the power amplifier on a basis of a digital ET mode, the first switch connects the voltage supply path to the ground through the resistor and the first capacitor, and wherein, in a state in which the plurality of discrete voltages are supplied to the power amplifier on the basis of an APT mode, the first switch does not connect the voltage supply path to the ground through the resistor and the first capacitor.

<8> The amplifier circuit according to <7>, wherein, in a state in which a continuous voltage is supplied to the power amplifier on a basis of an analog ET mode, the first switch does not connect the voltage supply path to the ground through the resistor and the first capacitor.

<9> The amplifier circuit according to <2> or <3>, wherein the first bypass capacitor circuit is connected between the ground and a path between the RC series circuit and the power amplifier.

<10> The amplifier circuit according to any one of <2>, <3> and <9>, wherein the first bypass capacitor circuit further includes a second switch connected between the second capacitor and the voltage supply path or the ground.

<11> The amplifier circuit according to <10>,

wherein the second switch is connected between the second capacitor and the ground.

<12> The amplifier circuit according to <10> or <11>, wherein, in a state in which the plurality of discrete voltages are supplied to the power amplifier on a basis of a digital ET mode, the second switch does not connect the voltage supply path to the ground through the second capacitor, and wherein, in a state in which the plurality of discrete voltages are supplied to the power amplifier on a basis of an APT mode, the second switch connects the voltage supply path to the ground through the second capacitor.

<13> The amplifier circuit according to <12>, wherein, in a state in which a continuous voltage is supplied to the power amplifier on a basis of an analog ET mode, the second switch does not connect the voltage supply path to the ground through the second capacitor.

<14> The amplifier circuit according to any one of <10> to <13>, further comprising: a second bypass capacitor circuit that includes a third capacitor connected in series between the voltage supply path and the ground, wherein the third capacitor has an electrostatic capacity smaller than an electrostatic capacity of the second capacitor.

<15> The amplifier circuit according to <14>, wherein the second bypass capacitor circuit is connected between the ground and a path between the RC series circuit and the power amplifier.

<16> The amplifier circuit according to <14> or <15>, wherein the second bypass capacitor circuit further includes a third switch connected between the third capacitor and the voltage supply path or the ground, wherein the amplifier circuit further includes a fourth capacitor connected between the voltage supply path and the ground, and wherein the fourth capacitor has an electrostatic capacity smaller than the electrostatic capacity of each of the second capacitor and the third capacitor.

<17> The amplifier circuit according to <16>, wherein the third switch is connected between the third capacitor and the ground.

<18> The amplifier circuit according to <16> or <17>, wherein, in a state in which the plurality of discrete voltages are supplied to the power amplifier on a basis of a digital ET mode and an APT mode, the third switch connects the voltage supply path to the ground through the third capacitor, and wherein, in a state in which a continuous voltage is supplied to the power amplifier on a basis of an analog ET mode, the third switch does not connect the voltage supply path to the ground through the third capacitor.

<19> An amplifying method for amplifying a radio frequency signal, comprising: receiving supply of a plurality of discrete voltages within one frame of the radio frequency signal; attenuating ringing of the plurality of discrete voltages by using an RC series circuit; and amplifying the radio frequency signal by using the plurality of discrete voltages whose ringing has been attenuated.

<20> The amplifying method according to <19>, further comprising: receiving supply of the plurality of discrete voltages in units of one frame of the radio frequency signal or larger units; in a state in which supply of the plurality of discrete voltages is received within one frame of the radio frequency signal, attenuating ringing of the plurality of discrete voltages by using the RC series circuit; and in a state in which supply of the plurality of discrete voltages is received in units of one frame of the radio frequency signal or larger units, not attenuating ringing of the plurality of discrete voltages by using the RC series circuit.

The exemplary aspects of the present disclosure may be used as an amplifier circuit, which is disposed in a frontend unit, broadly in communication devices such as a mobile phone.

### REFERENCE SIGNS LIST

1 radio frequency circuit

1M radio frequency module

2 antenna

3 RFIC

4 BBIC

5 tracker circuit

6 digital ET/APT

7 analog ET

8 mode switch

9 communication device

10 amplifier circuit

11, 12 power amplifier

13, 14, 15 matching circuit

16 PA control circuit

17 RC series circuit

18, 19 bypass capacitor circuit

20 filter

30, SW1, SW2, SW3 switch

90 module substrate

90a, 90b principal surface

100 antenna connection terminal

111 radio-frequency input terminal

112 power supply voltage terminal

113 control terminal

C1, C2, C3, C4 capacitor

L1, L2 inductor

P1 voltage supply path

P11, P12 point

R1 resistor

T1, T2 amplifier transistor

1. An amplifier circuit for amplifying a radio frequency signal by a plurality of discrete voltages supplied from a tracker circuit within one frame of the radio frequency signal, the amplifier circuit comprising:
a power amplifier; and
an RC series circuit that includes a resistor and a first capacitor connected in series between a ground and a voltage supply path between the tracker circuit and the power amplifier.

2. The amplifier circuit according to claim 1, further comprising a first bypass capacitor circuit that includes a second capacitor connected between the voltage supply path and the ground.

3. An amplifier circuit comprising:
a power amplifier;
an RC series circuit that includes a resistor and a first capacitor connected in series between a ground and a voltage supply path for the power amplifier; and
a first bypass capacitor circuit that includes a second capacitor connected between the ground and the voltage supply path.

4. The amplifier circuit according to claim 1, wherein, in the RC series circuit, the resistor is connected between the first capacitor and the voltage supply path.

5. The amplifier circuit according to claim 3, wherein the RC series circuit further includes a first switch connected in series to the resistor and the first capacitor.

6. The amplifier circuit according to claim 5, wherein the first switch is connected between the ground, and the resistor and the first capacitor.

7. The amplifier circuit according to claim 5,
wherein the first switch is configured to connect the voltage supply path to the ground through the resistor and the first capacitor when a plurality of discrete voltages are supplied to the power amplifier based on a digital ET mode, and
wherein, when the plurality of discrete voltages are supplied to the power amplifier based on an APT mode, the first switch is configured to not connect the voltage supply path to the ground through the resistor and the first capacitor.

8. The amplifier circuit according to claim 7, wherein, when a continuous voltage is supplied to the power amplifier based on an analog ET mode, the first switch is configured to not connect the voltage supply path to the ground through the resistor and the first capacitor.

9. The amplifier circuit according to claim 3, wherein the first bypass capacitor circuit is connected between the ground and a path between the RC series circuit and the power amplifier.

10. The amplifier circuit according to claim 3, wherein the first bypass capacitor circuit further includes a second switch connected between the second capacitor and the voltage supply path or the ground.

11. The amplifier circuit according to claim 10, wherein the second switch is connected between the second capacitor and the ground.

12. The amplifier circuit according to claim 10,
wherein the second switch is configured to not connect the voltage supply path to the ground through the second capacitor when a plurality of discrete voltages are supplied to the power amplifier based on a digital ET mode, and
wherein, when the plurality of discrete voltages are supplied to the power amplifier based on an APT mode, the second switch is configured to connect the voltage supply path to the ground through the second capacitor.

13. The amplifier circuit according to claim 12, wherein, when a continuous voltage is supplied to the power amplifier based on an analog ET mode, the second switch is configured to not connect the voltage supply path to the ground through the second capacitor.

14. The amplifier circuit according to claim 10, further comprising:
a second bypass capacitor circuit that includes a third capacitor connected in series between the voltage supply path and the ground,
wherein the third capacitor has an electrostatic capacity smaller than an electrostatic capacity of the second capacitor.

15. The amplifier circuit according to claim 14, wherein the second bypass capacitor circuit is connected between the ground and a path between the RC series circuit and the power amplifier.

16. The amplifier circuit according to claim 14,
wherein the second bypass capacitor circuit further includes a third switch connected between the third capacitor and the voltage supply path or the ground,
wherein the amplifier circuit further includes a fourth capacitor connected between the voltage supply path and the ground, and
wherein the fourth capacitor has an electrostatic capacity smaller than the electrostatic capacity of each of the second capacitor and the third capacitor.

17. The amplifier circuit according to claim 16, wherein the third switch is connected between the third capacitor and the ground.

18. The amplifier circuit according to claim 16,
wherein, the third switch is configured to connect the voltage supply path to the ground through the third capacitor when a plurality of discrete voltages are supplied to the power amplifier based on a digital ET mode and an APT mode, and
wherein, when a continuous voltage is supplied to the power amplifier on a basis of an analog ET mode, the third switch is configured to not connect the voltage supply path to the ground through the third capacitor.

19. An amplifying method for amplifying a radio frequency signal, the method comprising:
receiving a supply of a plurality of discrete voltages within one frame of the radio frequency signal;
attenuating, by an RC series circuit, ringing of the plurality of discrete voltages; and
amplifying the radio frequency signal using the plurality of discrete voltages having an attenuated ringing.

20. The amplifying method according to claim 19, further comprising:
receiving the supply of the plurality of discrete voltages in units of one frame of the radio frequency signal or larger units;
when the supply of the plurality of discrete voltages is received within the one frame of the radio frequency signal, attenuating ringing of the plurality of discrete voltages by the RC series circuit; and
when the supply of the plurality of discrete voltages is received in units of the one frame of the radio frequency signal or larger units, not attenuating ringing of the plurality of discrete voltages by the RC series circuit.
